(19) United States
(12) Patent Application Publication
(10) Pub. No.: US 2015/0377938 A1
(43) Pub. Date: Dec. 31, 2015

(54) SEASONALITY DETECTION IN TIME SERIES DATA

(71) Applicant: Microsoft Corporation, Redmond, WA (US)

(72) Inventors: Gagan Bansal, Sunnyvale, CA (US); Vijay K. Narayanan, Mountain View, CA (US); Abdullah Al Mueen, Albuquerque, NM (US)

(21) Appl. No.: 14/315,131

(22) Filed: Jun. 25, 2014

(51) Int. Cl. G01R 22/10

(52) U.S. Cl. CPC G01R 22/10

(57) ABSTRACT

A system that uses power spectrum analysis and auto-correlation function analysis to perform seasonality estimation of time series data. A power spectrum analyzer calculates and analyzes a power spectrum of a received time series data. An auto-correlation function analyzer calculates at least one auto-correlation function of the received time series, and generates a resulting set of one or more candidate seasonalities. A seasonality estimator estimates one or more seasonalities of the received time series using at least a portion of the analyzed result from the power spectrum analyzer and using the set of one or more candidates generated by the auto-correlation function analyzer. Accordingly, the estimation of candidate seasonality uses both auto-correlation and power spectrum analysis, thereby at least in some circumstances improving the seasonality estimation compared to auto-correlation function analysis alone or power spectrum analysis alone.

### BACKGROUND

Computing systems and associated networks have revolutionized the way human beings work, play, and communicate. Nearly every aspect of our lives is affected in some way by computing systems. The functionality of a computing system is largely driven by the instructions that are executed by the one or more processors of the computing system. Such instructions are often referred collectively referred to as “software”.

One of the most helpful aspects of a computing system is the ability to analyze and provide insight into the meaning of even large quantities of data (often referred to in the industry as “big data”), that simply would not be possible using a human mind alone. One aspect of such analysis is the detection of “seasonality” of a particular data set.

“Seasonality” (or “periodicity”) is defined as the number of time steps after which a time series process tends to repeat itself. Many natural processes around us demonstrate seasonal behavior. For example, the rotation of planets around the sun is a seasonal process having a seasonality of one year (by definition). The heart beat in humans is also a seasonal process having a seasonality of about one second or in the order of a second. Detecting deviations from seasonal behavior is also helpful in many domains. For instance, human eye blinking is typically seasonal, and deviations from the normal seasonality are used to diagnose Tourette's syndrome. Accordingly, accurate estimation of seasonality is extremely important. Further, seasonality estimation is an important first step in several time series forecasting applications like weather forecasting and sales forecasting. Popular time series forecasting algorithms like Exponential Time Smoothing (ETS) and Auto-Regressive Integrated Moving Average (ARIMA) need the seasonality as an input and are often very sensitive to different values of input seasonality.

Traditional methods of estimating the seasonality use power spectrum or the auto-correlation function (ACF) of the input time series data. Power spectrum analysis to estimate seasonality exploits the property that the maximum power in the power spectrum of the time series occurs at the frequency corresponding to the period of the series. Auto-correlation function analysis exploits the property that there is a peak in the auto-correlation function at a lag equal to the period of the series.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

At least some embodiments described herein relate to the use of a computing system to estimate seasonality in time series data. The system uses power spectrum analysis and auto-correlation function analysis to perform the estimation.

A power spectrum analyzer calculates and analyzes a power spectrum of a received time series data. An auto-correlation function analyzer calculates at least one auto-correlation function of the received time series, and generates a resulting set of one or more candidate seasonalities. A seasonality estimator estimates one or more seasonalities of the received time series using at least a portion of the analyzed result from the power spectrum analyzer and using the set of one or more candidates generated by the auto-correlation function analyzer. Accordingly, the estimation of candidate seasonality uses both auto-correlation and power spectrum analysis, thereby at least in some circumstances improving the seasonality estimation compared to auto-correlation function analysis alone or power spectrum analysis alone.

This Summary is not intended to identify key features or essential features of the claimed subject matter, nor is it intended to be used as an aid in determining the scope of the claimed subject matter.

### BRIEF DESCRIPTION OF THE DRAWINGS

In order to describe the manner in which the above-recited and other advantages and features can be obtained, a more particular description of various embodiments will be rendered by reference to the appended drawings. Understanding that these drawings depict only sample embodiments and are not therefore to be considered to be limiting of the scope of the invention, the embodiments will be described and explained with additional specificity and detail through the use of the accompanying drawings in which:

FIG. 1 abstractly illustrates a computing system in which some embodiments described herein may be employed;

FIG. 2 illustrates a system that receives as input time series data and generates a resulting estimate of one or more seasonalities of the time series data;

FIG. 3 illustrates a flowchart of a method for estimating a seasonality of time series data using a computing system, such as the system of FIG. 2; and

FIG. 4 illustrates a system that represents an example of the system of FIG. 2.

### DETAILED DESCRIPTION

At least some embodiments described herein relate to the use of a computing system to estimate seasonality in time series data. The system uses power spectrum analysis and auto-correlation function analysis to perform the estimation.

A power spectrum analyzer calculates and analyzes a power spectrum of a received time series data. An auto-correlation function analyzer calculates at least one auto-correlation function of the received time series, and generates a resulting set of one or more candidate seasonalities. A seasonality estimator estimates one or more seasonalities of the received time series using at least a portion of the analyzed result from the power spectrum analyzer and using the set of one or more candidates generated by the auto-correlation function analyzer. Accordingly, the estimation of candidate seasonality uses both auto-correlation and power spectrum analysis, thereby at least in some circumstances improving the seasonality estimation compared to auto-correlation function analysis alone or power spectrum analysis alone.

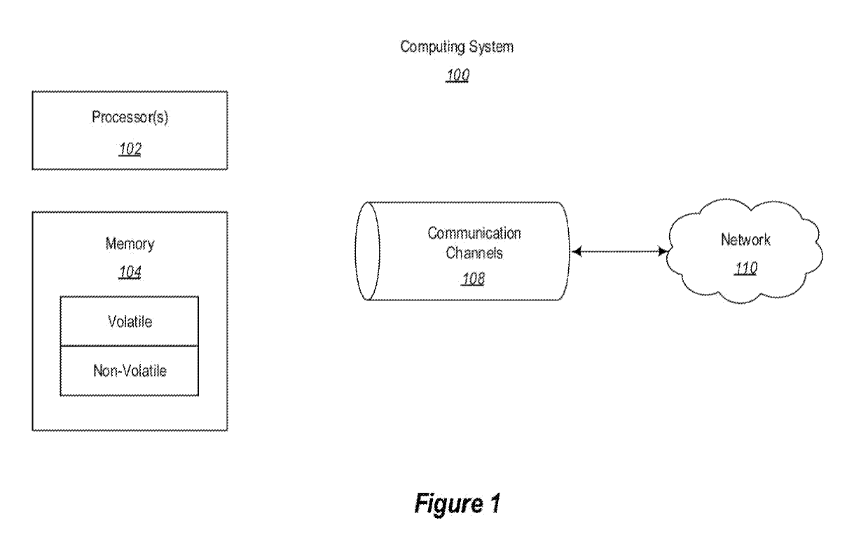

Some introductory discussion of a computing system will be described with respect to FIG. 1. Then, the seasonality estimation in accordance with embodiments described herein will be described with respect to subsequent figures.

Computing systems are now increasingly taking a wide variety of forms. Computing systems may, for example, be handheld devices, appliances, laptop computers, desktop computers, mainframes, distributed computing systems, or even devices that have not conventionally been considered a computing system. In this description and in the claims, the term “computing system” is defined broadly as including any device or system (or combination thereof) that includes at least one physical and tangible processor, and a physical and tangible memory capable of having thereon computer-executable instructions that may be executed by the processor. The memory may take any form and may depend on the nature and form of the computing system. A computing system may be distributed over a network environment and may include multiple constituent computing systems.

As illustrated in FIG. 1, in its most basic configuration, a computing system 100 typically includes at least one hardware processing unit 102 and memory 104. The memory 104 may be physical system memory, which may be volatile, non-volatile, or some combination of the two. The term “memory” may also be used herein to refer to non-volatile mass storage such as physical storage media. If the computing system is distributed, the processing, memory and/or storage capability may be distributed as well. As used herein, the term “executable module” or “executable component” can refer to software objects, routings, or methods that may be executed on the computing system. The different components, modules, engines, and services described herein may be implemented as objects or processes that execute on the computing system (e.g., as separate threads).

In the description that follows, embodiments are described with reference to acts that are performed by one or more computing systems. If such acts are implemented in software, one or more processors of the associated computing system that performs the act direct the operation of the computing system in response to having executed computer-executable instructions. For example, such computer-executable instructions may be embodied on one or more computer-readable media that form a computer program product. An example of such an operation involves the manipulation of data. The computer-executable instructions (and the manipulated data) may be stored in the memory 104 of the computing system 100. Computing system 100 may also contain communication channels 108 that allow the computing system 100 to communicate with other message processors over, for example, network 110. The computing system 100 also includes a display, which may be used to display visual representations to a user.

Embodiments described herein may comprise or utilize a special purpose or general-purpose computer including computer hardware, such as, for example, one or more processors and system memory, as discussed in greater detail below. Embodiments described herein also include physical and other computer-readable media for carrying or storing computer-executable instructions and/or data structures. Such computer-readable media can be any available media that can be accessed by a general purpose or special purpose computer system. Computer-readable media that store computer-executable instructions are physical storage media. Computer-readable media that carry computer-executable instructions are transmission media. Thus, by way of example, and not limitation, embodiments of the invention can comprise at least two distinctly different kinds of computer-readable media: computer storage media and transmission media.

Computer storage media includes RAM, ROM, EEPROM, CD-ROM or other optical disk storage, magnetic disk storage or other magnetic storage devices, or any other storage medium which can be used to store desired program code means in the form of computer-executable instructions or data structures and which can be accessed by a general purpose or special purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmissions media can include a network and/or data links which can be used to carry desired program code means in the form of computer-executable instructions or data structures and which can be accessed by a general purpose or special purpose computer. Combinations of the above should also be included within the scope of computer-readable media.

Further, upon reaching various computer system components, program code means in the form of computer-executable instructions or data structures can be transferred automatically from transmission media to computer storage media (or vice versa). For example, computer-executable instructions or data structures received over a network or data link can be buffered in RAM within a network interface module (e.g., a “NIC”), and then eventually transferred to computer system RAM and/or to less volatile computer storage media at a computer system. Thus, it should be understood that computer storage media can be included in computer system components that also (or even primarily) utilize transmission media.

Computer-executable instructions comprise, for example, instructions and data which, when executed at a processor, cause a general purpose computer, special purpose computer, or special purpose processing device to perform a certain function or group of functions. The computer executable instructions may be, for example, binaries or even instructions that undergo some translation (such as compilation) before direct execution by the processors, such as intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, and the like. The invention may also be practiced in distributed system environments where local and remote computer systems, which are linked (either by hardwired data links, wireless data links, or by a combination of hardwired and wireless data links) through a network, both perform tasks. In a distributed system environment, program modules may be located in both local and remote memory storage devices.

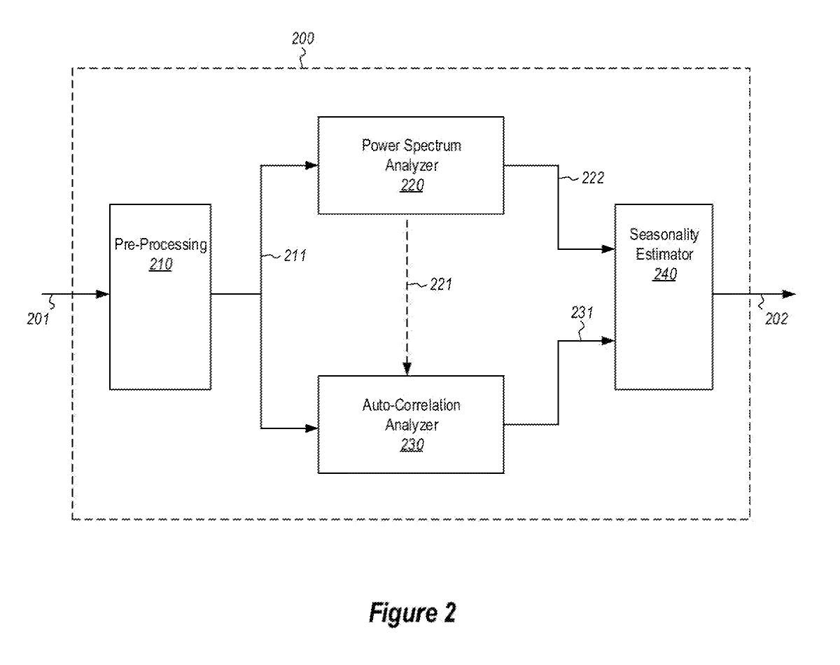

FIG. 2 illustrates a system 200 that receives as input time series data 201 and generates a resulting estimate of one or more seasonalities 202 of the time series data 201. The system 200 includes a pre-processing component 210, a power spectrum analyzer 220, an auto-correlation function analyzer 230, and a seasonality estimator 240. In one embodiment, the system 200 might be embodied within the computing system 100 of FIG. 1, considering that the computing system 100 may be distributed. For instance, the components 210, 220, 230 and 240 might be components (e.g., objects, routines, functions, methods, components, modules, of the like) that operate within the computing system. The system 200 may be operated and/or instantiated by one or more processors of a computing system executing one or more computer-executable instructions embodied on a computer-readable media, such as a computer-readable storage media.

As previously mentioned, conventional attempts at seasonality estimation of time series data use either frequency based methods (such as power spectrum analysis) or auto-correlation function analysis. Frequency based methods use the power at discrete values of frequency (typically 1/N, 2/N, . . . , (N/2)/N or 0.5, where N is the length of the data). Thus, frequency based method can only most accurately output periods of the form N/2, N/3, . . . , 2 but are less able or unable to detect periods at a finer granularity than the size of the frequency bins. For example, the frequency based methods can detect a period of 5 in a series of length 20, but are less able or are unable to detect a period of length 6 in the same series.

Auto-correlation frequency based methods detect the peak in the auto-correlation function, and use that as the estimated seasonality of the time series data. To find peaks in auto-correlation function, the method uses heuristics like that the auto-correlation function value at the peak should be more than the auto-correlation value at the neighboring lags. However, the method becomes noisy for very small periods like 2 and 3 samples because their neighborhood contains (lag=0) at which the auto-correlation function value is the maximum or at large periods where it is difficult to detect peaks because the auto-correlation function has small values.

In accordance with the principles described herein, power spectrum analyses and auto-correlation function analysis are performed in a symbiotic way, leading to potentially better estimation (at least under some circumstances) as compared to using one of the analyses types, or even using both of the analysis types independently.

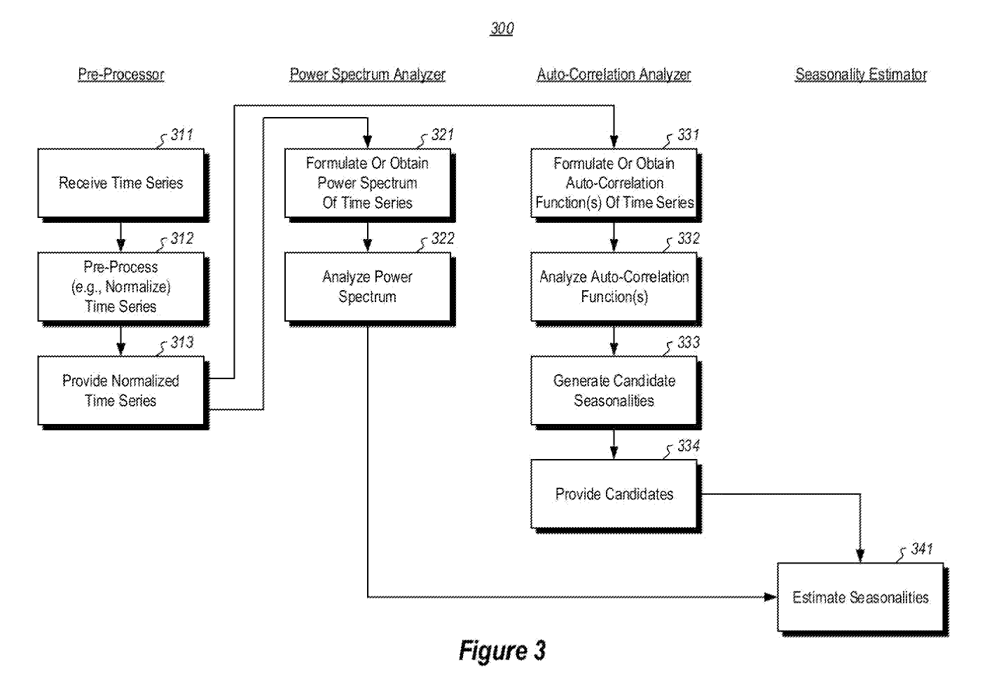

FIG. 3 illustrates a flowchart of a method 300 for estimating a seasonality of time series data using a computing system. As the method 300 may be performed by the system 200 of FIG. 2, the operation of the system 200 will now be described with frequent reference to the method 300 of FIG. 3. Furthermore, the acts in the method 300 of FIG. 3 that may be performed by the various components 210, 220, 230 and 240 of FIG. 2 are illustrated in FIG. 2 under respective headers. That said, the principles described herein are not limited to the particular described acts being performed by any specific component.

The pre-processing component 210 of the system 200 receives the time series data (act 311). For instance, this receipt of the input time series data is abstractly represented in FIG. 2 by arrow 201. The pre-processing component 210 also pre-processes the time series data (act 312). The pre-processing component 210 is an optional component. Alternatively, the power spectrum analyzer 220 and the auto-correlation function analyzer 230 might directly receive and process the time series data. In one example, the pre-processing component 210 removes linearity in the time series data such also adds a positive or negative scalar to the resulting time series data such that there is little or no linearity in the time series data, and such that the mean of the time series data tends to be zero. The pre-processor 210 might also determine the standard deviation of the time series data, and divide the time series data by the standard deviation. The pre-processing component 210 then provides (act 313) the normalized time series data to the power spectrum analyzer 220 and the auto-correlation function analyzer. In FIG. 2, this providing is abstractly represented by double headed arrow 211.

The power spectrum analyzer 220 of the system 200 formulates (e.g., calculates) a power spectrum (act 321) of the time series data. For instance, the power spectrum analyzer 220 might perform a Fourier transform of the time series data. The power spectrum analyzer 220 also analyzes (act 322) the resulting power spectrum of the time series data.

The auto-correlation function analyzer 230 of the system 200 formulates (act 331) (e.g., calculates) at least one auto-correlation function of the received time series. The auto-correlation function analyzer 230 then analyzes (act 332) the auto-correlation function(s) of the received time series. Based on this analysis, the auto-correlation function analyzer 230 generates (act 333) a set of one or more candidate seasonalities from one or more of the at least one auto-correlation function. Optionally, the auto-correlation function analyzer 230 generates the set of one or more candidate seasonalities using an analyzed result from the power spectrum analyzer 220. This use is represented in FIG. 2 by the dashed arrow 221. The auto-correlation function analyzer 230 provides (act 334) the resulting candidate seasonalities, for instance, to the seasonality estimator 240, as also represented by arrow 231 in FIG. 2.

The seasonality estimator 240 estimates (act 341) one or more seasonalities of the received time series using 1) at least a portion of the analyzed result from the power spectrum analyzer 220 (as represented by arrow 222) and 2) the set of one or more candidates generated by the auto-correlation function analyzer 230 (as represented by arrow 221).

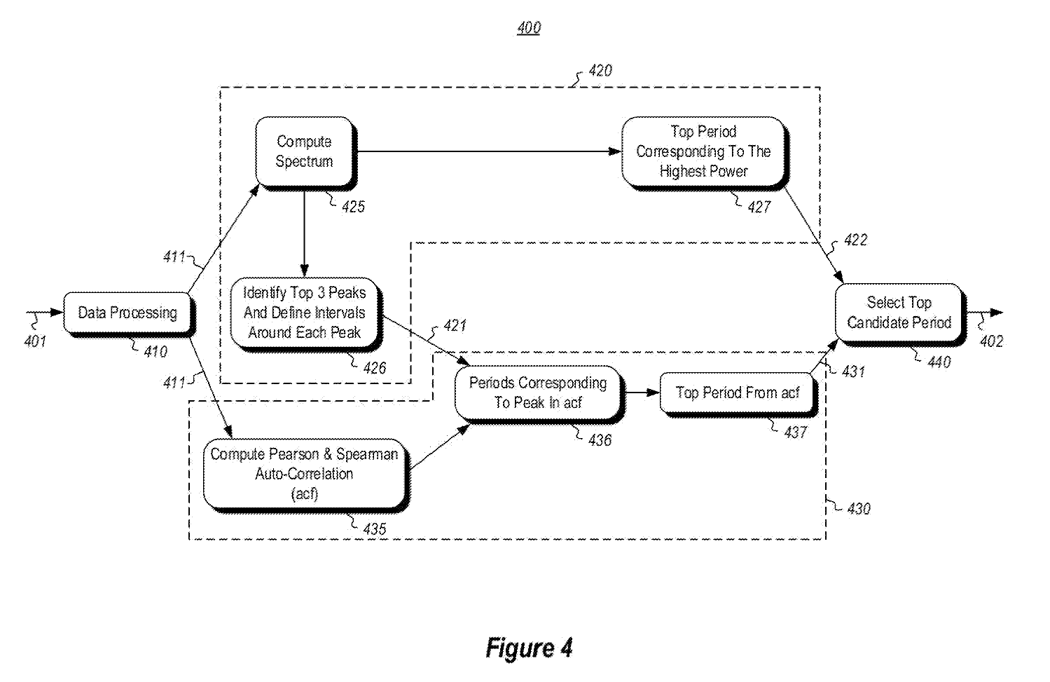

FIG. 4 illustrates a system 400 that represents an example of the system 200 of FIG. 2. The system 400 includes a pre-processing component 410, a power spectrum analyzer 420, an auto-correlation function analyzer 430, and a seasonality estimator 440, which are each respective examples of the components 210, 220, 230 and 240 of FIG. 2. Also, flows 401, 402 411, 421, 422 and 431 of FIG. 4 represent respective examples of the flows 201, 202, 211, 221, 222 and 231 in FIG. 2.

The operation of the pre-processing component 410 is the same as that described for the pre-processing component 210. For instance, a linear trend is removed by regressing the time data series against time and computing the residuals. The residual time series is then further z-normalized by subtracting the mean and dividing by the standard deviation.

As for the power spectrum analyzer 420, the component 425 computes the power spectrum. The component 426 identifies the top N peaks (e.g., where N is a positive integer) of the power spectrum, and defines intervals around each peak by including the adjacent bins in the frequency domain. For instance, suppose that N is three, three frequency intervals would be defined, each centered in the frequency domain around one of the top three highest powered frequencies.

The component 426 further modifies the interval boundaries to include any common business seasonality if the interval boundary lies close to the business seasonality. For instance, suppose that one of the power peaks was found at a frequency of 0.8 per year. The corresponding interval might thus be defined as 0.7 per year to 0.9 per year (if the amount of the interval extends 0.1 per year in both directions around the peak). However, 1 per year might be a common seasonality. Often time series data tends to have an annual cyclic component. In that case, so as not to exclude this common business seasonality, the time interval might be extended from perhaps 0.7 per year to 1.1 per year. The corresponding candidate time periods are then provided by the power spectrum analyzer 420 to the auto-correlation function analyzer 430 as represented by arrow 421. This represents an example of how the auto-correlation function analyzer 430 might use at least a portion of results of the power spectrum analyzer's analysis of the power spectrum.

The component 427 also analyzes the power spectrum to find the frequency at which the power is at a maximum. The corresponding time representation for that frequency is then provided (as represented by arrow 422) as a candidate seasonality from the power spectrum analyzer 420. In other embodiments, the power spectrum analyzer 420 may also output M time representations (representing M candidate seasonalities) of the corresponding top M power peaks detected in the power spectrum of the time series (where M may be any position integer). Accordingly, in this embodiment, the power spectrum analyzer 420 generates another set of one or more candidate seasonalities from the time series using the power spectrum. The seasonality estimator 440 may then estimate seasonality using both the set of candidate seasonalities received (as represented by arrow 422) from the power spectrum analyzer 420 in conjunction with the set of one or more candidate seasonalities received (as represented by arrow 421) from the auto-correlation function analyzer 430.

As for the auto-correlation function analyzer 430, the component 435 receives the normalized time series data as represented by the lower arrow 411. The component 435 further computes two auto-correlation functions corresponding to this pre-processed time series data. Specifically, the component 435 might compute a Pearson auto-correlation function, and also a Spearman auto-correlation function.

The component 436 evaluates each auto-correlation function within the candidate time periods provided by the power spectrum analyzer 420. For instance, if the power spectrum analyzer 420 provided three such candidate time intervals, and there are two auto-correlation functions generated, then there is the possibility of the component 436 finding up to 6 peaks (if all of the candidate time intervals happen to have a peak for both auto-correlation functions).

The component 436 find peaks in the Pearson and Spearman auto-correlation in the candidate time intervals found from the power spectrum (the peak being the highest auto-correlation value in the interval as the peak). The component 436 searches for hills in each candidate time interval for each auto-correlation function, by fitting two line segments between the candidate time interval boundaries where each line segment is of length at least 3 and pick the two line segments that minimize the mean squared error. If these 2 line segments (of slopes slope1 and slope2) are such that slope1 is positive and slope2 is negative, then the component 436 detects that there is a hill in the candidate time interval. If a hill is not detected, the component 436 checks the next harmonic for a hill and the component 436 detects a hill in the next harmonic, the component 436 reports the peak as harmonic_peak/2 (where harmonic_peak is the detected peak in the next harmonic).

The component 437 then selects the best reported peak amongst those peaks that appear in any of the candidate time intervals for which a hill is found in the time interval itself or in its first harmonic. The component 437 arranges the detected peaks in decreasing order of power. As an initial cut, the component only considers the top k peaks if the power at the k^{th} peak is at least two times greater than the power of the k+1'^{th} peak. For instance, if the powers of 4 detected peaks for which there was a hill in the candidate time interval was arranged to be 10, 6, 2, and 1, only the peaks having powers of 10 and 6 would survive the cut based on power (because 6 is more than a factor of 2 greater than 2). If there were 3 detected peaks in the intervals for which a hill was found and the arranged powers were 7, 2 and 1.5, then only the peak having power 7 would survive the cut (because 7 is more than a factor of 2 greater than 2). If there were 3 detected peaks in the intervals for which a hill was found and the arranged powers were 7, 4 and 1.5, then the peaks having powers 7 and 4 would survive the cut.

Then, of those peaks that survived the cut, the peak with the highest auto-correlation value is selected. The candidate seasonality corresponding to this peak is then selected and sent (as represented by arrow 431) to the seasonality estimator 440. Accordingly, the selection of the best peak (and thus the selection of the candidate seasonality) provided by the auto-correlation function analyzer 430 is determined using both an auto-correlation value and a power.

The seasonality estimator 440 then estimates the seasonality of the time series data by using selection criteria to select the best candidate seasonality provided by the power spectrum analyzer 420 or the auto-correlation function analyzer 430. For instance, if there is no candidate seasonality provided by the auto-correlation function analyzer 430, then the candidate seasonality provided by the power spectrum analyzer 420 is selected. If the candidate seasonality from the auto-correlation function analyzer 430 has an auto-correlation value of less than 6, the seasonality estimator 440 finds the length normalized powers of the candidate seasonality from the power spectrum analyzer 420 and the candidate seasonality from the auto-correlation function analyzer 430, and selects the candidate seasonality corresponding to the peak with higher power. If the candidate seasonality from the auto-correlation function analyzer 420 has a peak corresponding to an auto-correlation value of greater than 6, then that seasonality estimator 440 selects the candidate seasonality provided by the auto-correlation function analyzer 440.

Accordingly, the principles described herein provide a system that estimates seasonality using a combination of power spectrum analysis, and auto-correlation function analysis, and thus provides accurate seasonality estimation even where one or both of the power spectrum analysis or the auto-correlation function analysis might provide weak results.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A computer program product comprising one or more computer-readable storage media having thereon one or more computer-executable instructions that are structured such that, when executed by one or more processors of a computing system, cause the computing system to operate and/or instantiate the following:
a power spectrum analyzer that calculates and analyzes a power spectrum of a received time series;
an auto-correlation function analyzer that calculates at least one auto-correlation function of the received time series, and generates a set of one or more candidate seasonalities from one or more of the at least one auto-correlation function; and
a seasonality estimator that estimates one or more seasonalities of the received time series using at least a portion of the analyzed result from the power spectrum analyzer and using the set of one or more candidates generated by the auto-correlation function analyzer.

2. The computer program product in accordance with claim 1, the set of one or more candidate seasonalities generated by the auto-correlation function analyzer being a first set of one or more candidate seasonalities, the power spectrum analyzer also generating a second set of one or more candidate seasonalities from the time series using the power spectrum, the seasonality estimator also estimating the one or more seasonalities using the second set of one or more candidate seasonalities generated by the power spectrum analyzer.

3. The computer program product in accordance with claim 2, wherein the seasonality estimator estimates the one or more seasonalities of the time series by applying selection criteria to select from the first set of one or more candidate seasonalities generated by the auto-correlation function analyzer and the second set of one or more candidate seasonalities generated by the power spectrum analyzer.

4. The computer program product in accordance with claim 3, the selection criteria including a power and an auto-correlation value of the auto-correlation function at the time corresponding to each candidate seasonality.

5. The computer program products in accordance with claim 1, the second set of one or more candidate seasonalities being time representations of corresponding sets of one of more frequencies of the power spectrum for which power peaks are detected by the power spectrum analyzer.

6. The computer program product in accordance with claim 1,
the auto-correlation function analyzer generating the set of one or more candidate seasonalities from one or more of the at least one auto-correlation function using at least a portion of the analyzed result from the power spectrum analyzer.

7. The computer program product in accordance with claim 6, the portion of the analyzed results used by the auto-correlation function analyzer comprising a plurality of candidate time periods.

8. The computer program product in accordance with claim 7, the auto-correlation function analyzer configured to:
formulate an auto-correlation function of the time series;
search for hills within each of at least some of the plurality of candidate time periods in the auto-correlation function of the time series;
for each of least some of the plurality of candidate time periods for which the auto-correlation analyzer finds a hill with the auto-correlation function of the time series, an act of searching for a peak within the auto-correlation function to result in a plurality of found peaks; and
an act of determining a candidate seasonality corresponding to a best peak within the auto-correlation function from amongst the found peaks.

9. The computer program product in accordance with claim 8, the act of determining a best peak within the auto-correlation function comprising using both an auto-correlation value and a power at each of at least some of the found peaks.

10. The computer program product in accordance with claim 1, the one or more computer-readable storage media having thereon one or more computer-executable instructions that are structured such that, when executed by one or more processors of a computing system, cause the computing system to operate and/or instantiate the following:
a pre-processing component configured to pre-process the time series prior to providing to the power spectrum analyzer and the auto-correlation function analyzer, the pre-processing include at least partially removing linear components of the time series, and normalizing the time series by standard deviation.

11. A method for estimating a seasonality of time series data using a computing system, the method comprising:
an act of obtaining a power spectrum of the time series data;
an act of using a power spectrum analyzer to analyze the power spectrum of the time series data;
an act of obtaining at least one auto-correlation function of the time series data;
an act of using an auto-correlation function analyzer to analyze the at least one auto-correlation function;
an act of using the auto-correlation function analyzer to generate a set of one or more candidate seasonalities of the time series data; and
an act of using a seasonality estimator to estimate one or more seasonalities of the time series data using at least a portion of a result of the analysis from the power spectrum analyzer and using the set of one or more candidate seasonalities generated by the auto-correlation function analyzer.

12. The method in accordance with claim 11, the set of one or more seasonalities generated by the auto-correlation function analyzer being a first set of one or more candidate seasonalities, the method also comprising:
an act of using the power spectrum analyzer to generate a second set of one or more candidate seasonalities from the time series data; and
the act of using the seasonality estimator to estimate the one or more seasonalities is performed also using the second set of one or more candidate seasonalities generated by the power spectrum analyzer.

13. The method in accordance with claim 11, the second set of one or more candidate seasonalities being time representations of corresponding sets of one of more frequencies of the power spectrum for which power peaks are detected by the power spectrum analyzer.

14. The method in accordance with claim 11, the act of using the auto-correlation function analyzer to generate the set of one or more candidate seasonalities using at least a portion of a result of the analysis of the power spectrum performed by the power spectrum analyzer.

15. The method in accordance with claim 14, the portion of the analyzed results used by the auto-correlation function analyzer comprising a plurality of candidate time periods.

16. The method in accordance with claim 15, the act of using the auto-correlation function analyzer to generate the set of one or more candidate seasonalities of the time series data comprising:
an act of using the auto-correlation function analyzer to search for hills within each of at least some of the plurality of candidate time periods in an auto-correlation function of the time series data;
for each of least some of the plurality of candidate time periods for which the auto-correlation function analyzer finds a hill with the auto-correlation function of the time series, an act using the auto-correlation function analyzer to search for a peak within the auto-correlation function to result in a plurality of found peaks; and
an act of causing the auto-correlation function analyzer to determine a candidate seasonality corresponding to a best peak within the auto-correlation function from amongst the found peaks.

17. The method in accordance with claim 16, the auto-correlation function analyzer determining a best peak within the auto-correlation function using both an auto-correlation value and a power at each of at least some of the found peaks.

18. The method in accordance with claim 11, further comprising:
an act of using a pre-processing component to pre-process the time series data prior to providing to the power spectrum analyzer and the auto-correlation function analyzer.

19. The method in accordance with claim 18, the auto-correlation function being a first auto-correlation function, the plurality of found peeks being a first plurality of found peeks, the act of using the auto-correlation function analyzer to generate the set of one or more candidate seasonalities of the time series data comprising:
an act of using the auto-correlation function analyzer to search for hills within each of at least some of the plurality of candidate time periods in a second auto-correlation function of the time series data;
for each of least some of the plurality of candidate time periods for which the auto-correlation analyzer finds a hill with the second auto-correlation function of the time series, an act using the auto-correlation function analyzer to search for a peak within the second auto-correlation function to result in a second plurality of found peaks; and
an act of causing the auto-correlation function analyzer to determine a candidate seasonality corresponding to a best peak within the auto-correlation function from amongst the first plurality of found peaks and the second plurality of found peaks.

20. A computing system comprising:
one or more processors;
one or more computer-readable storage media having thereon one or more computer-executable instructions that are structured such that, when executed by one or more processors of a computing system, cause the computing system to operate and/or instantiate the following:
a power spectrum analyzer that calculates and analyzes a power spectrum of a received time series;
an auto-correlation function analyzer that calculates at least one auto-correlation function of the received time series, and generates a set of one or more candidate seasonalities from one or more of the at least one auto-correlation function; and
a seasonality estimator that estimates one or more seasonalities of the received time series using at least a portion of the analyzed result from the power spectrum analyzer and using the set of one or more candidates generated by the auto-correlation function analyzer.
